(19) United States
(12) Patent Application Publication
(10) Pub. No.: US 2016/0143143 A1
(43) Pub. Date: May 19, 2016

(54) OPTOELECTRONIC MODULES AND ASSEMBLIES COMPRISING OPTOELECTRONIC MODULES

(71) Applicant: CORNING OPTICAL COMMUNICATIONS WIRELESS LTD., AIRPORT CITY, IL (US)

(72) Inventors: Eli Deri, Shaare Tikva, IL (US); Ami Hazani, Ra'anana, IL (US); Pinhas Yehuda Rosenfelder, Beit-Shemesh, IL (US)

(21) Appl. No.: 14/541,471

(22) Filed: Nov. 14, 2014

(51) Int. Cl. H05K 1/14; H01R 27/02; H01R 43/20; H01S 5/022; H05K 1/11; H05K 3/34; H05K 3/36; H01L 31/02; H01R 12/70; H05K 1/18

(52) U.S. Cl. CPC H05K 1/141; H01R 12/7076; H01R 27/02; H01R 43/205; H05K 1/181; H05K 1/115; H05K 3/3421; H05K 3/36; H01L 31/02; H01S 5/02236

(57) ABSTRACT

Optoelectronic modules and assemblies comprising optoelectronic modules are provided. An optoelectronic module includes an optoelectronic module printed circuit board, an optoelectronic component mounted to the optoelectronic module printed circuit board, an electrical connector affixed to the optoelectronic module printed circuit board, and a mounting bracket affixed to the optoelectronic module printed circuit board. The electrical connector is in electrical communication with an input of the optoelectronic component. The electrical connector is configured to removably plug into a mating electrical connector of a main printed circuit board. The mounting bracket includes an optoelectronic component engagement surface for engaging the optoelectronic component. The mounting bracket further includes a main printed circuit board engagement surface for engaging the main printed circuit board.

### BACKGROUND

1. Field

The present disclosure generally relates to modules and assemblies and, more particularly, to optoelectronic modules and assemblies comprising optoelectronic modules.

2. Technical Background

Optoelectronic components, such as laser diodes and photodiodes, may be used in a variety of applications, such as to transmit information via light. In many applications that utilize optoelectronic components, the optoelectronic components are electrically connected to other electronic components. In such applications, it may be desirable to interconnect the optoelectronic components with other electronic components in a convenient, space saving, and economical manner.

Accordingly, a need exists for optoelectronic modules and assemblies comprising optoelectronic modules.

### SUMMARY

In one embodiment, an assembly includes an optoelectronic module coupled to a main printed circuit board. The optoelectronic module includes an optoelectronic module printed circuit board, an optoelectronic component mounted to the optoelectronic module printed circuit board, an electrical connector affixed to the optoelectronic module printed circuit board, and a mounting bracket affixed to the optoelectronic module printed circuit board. The electrical connector is in electrical communication with an input of the optoelectronic component. The mounting bracket includes an optoelectronic component engagement surface for engaging the optoelectronic component. The mounting bracket further includes a main printed circuit board engagement surface that engages the main printed circuit board. The main printed circuit board includes a mating electrical connector. The electrical connector of the optoelectronic module is removably plugged into the mating electrical connector of the main printed circuit board, such that the electrical connector of the optoelectronic module is in electrical communication with the mating electrical connector of the main printed circuit board. The mounting bracket is secured to the main printed circuit board such that the optoelectronic module is coupled to the main printed circuit board.

In another embodiment, an assembly includes an optoelectronic module coupled to a main printed circuit board. The optoelectronic module includes an optoelectronic module printed circuit board, an optoelectronic component mounted to the optoelectronic module printed circuit board, a radio frequency electrical connector affixed to the optoelectronic module printed circuit board, a digital electrical connector affixed to the optoelectronic module printed circuit board, and a mounting bracket affixed to the optoelectronic module printed circuit board. The optoelectronic component has a transistor outline semiconductor package. The radio frequency electrical connector is in electrical communication with a radio frequency input of the optoelectronic component. The digital electrical connector is in electrical communication with a digital input of the optoelectronic component. The mounting bracket includes an optoelectronic component engagement surface for engaging the optoelectronic component. The mounting bracket further includes a main printed circuit board engagement surface for engaging the main printed circuit board. The main printed circuit board includes a mating radio frequency electrical connector and a mating digital electrical connector. The radio frequency electrical connector of the optoelectronic module is removably plugged into the mating radio frequency electrical connector of the main printed circuit board, such that the radio frequency electrical connector of the optoelectronic module is in electrical communication with the mating radio frequency electrical connector of the main printed circuit board. The digital electrical connector of the optoelectronic module is removably plugged into the mating digital electrical connector of the main printed circuit board, such that the digital electrical connector of the optoelectronic module is in electrical communication with the mating digital electrical connector of the main printed circuit board. The mounting bracket is secured to the main printed circuit board such that the optoelectronic module is coupled to the main printed circuit board.

In yet another embodiment, an optoelectronic module includes an optoelectronic module printed circuit board, an optoelectronic component mounted to the optoelectronic module printed circuit board, an electrical connector affixed to the optoelectronic module printed circuit board, and a mounting bracket affixed to the optoelectronic module printed circuit board. The electrical connector is in electrical communication with an input of the optoelectronic component. The electrical connector is configured to removably plug into a mating electrical connector of a main printed circuit board. The mounting bracket includes an optoelectronic component engagement surface for engaging the optoelectronic component. The mounting bracket further includes a main printed circuit board engagement surface for engaging the main printed circuit board.

In yet another embodiment, a method of assembling an optoelectronic module and a main printed circuit board includes providing an optoelectronic module. The optoelectronic module includes an optoelectronic module printed circuit board, an optoelectronic component mounted to the optoelectronic module printed circuit board, an electrical connector affixed to the optoelectronic module printed circuit board, and a mounting bracket affixed to the optoelectronic module printed circuit board. The electrical connector is in electrical communication with an input of the optoelectronic component. The mounting bracket includes an optoelectronic component engagement surface for engaging the optoelectronic component. The mounting bracket further includes a main printed circuit board engagement surface that engages the main printed circuit board. The method further includes providing the main printed circuit board having a mating electrical connector, and plugging the electrical connector of the optoelectronic module into the mating electrical connector of the main printed circuit board, such that the electrical connector of the optoelectronic module is in electrical communication with the mating electrical connector of the main printed circuit board.

In yet another embodiment, a method of assembling an optoelectronic module includes providing an optoelectronic module printed circuit board including a plurality of vias and a plurality of soldering pads offset from the plurality of vias, affixing an electrical connector to the optoelectronic module printed circuit board, affixing a mounting bracket to the optoelectronic module printed circuit board, mounting an optoelectronic component to the optoelectronic module with the mounting bracket, passing a plurality of pins of the optoelectronic component through the plurality of vias of the optoelectronic module printed circuit board, and soldering the plurality of pins to the plurality of soldering pads.

Additional features and advantages will be set forth in the detailed description which follows, and in part will be readily apparent to those skilled in the art from that description or recognized by practicing the embodiments as described herein, including the detailed description which follows, the claims, as well as the appended drawings.

The foregoing general description and the detailed description are merely exemplary, and provide an overview or framework to understanding the nature and character of the claims. The drawings are included to provide a further understanding, and are constitute a part of this specification. The drawings illustrate embodiments, and together with the description, serve to explain principles and operation of the various embodiments.

### BRIEF DESCRIPTION OF THE DRAWINGS

FIG. 1 schematically depicts a perspective view of a distributed antenna system module including a main printed circuit board and a plurality of laser diodes coupled to the main printed circuit board, according to one or more embodiments shown and described herein;

FIG. 2 schematically depicts an exploded view of an assembly including a main printed circuit board and an optoelectronic module, according to one or more embodiments shown and described herein;

FIG. 3 schematically depicts a bottom view of the optoelectronic module of FIG. 2, according to one or more embodiments shown and described herein;

FIG. 4 schematically depicts a circuit diagram illustrating the interconnection of a radio frequency electrical connector and a digital electrical connector to conductive pin inputs of an optoelectronic component, according to one or more embodiments shown and described herein;

FIGS. 5A and 5B schematically depict a rear perspective view (FIG. 5A) and front perspective view (FIB. 5B) of an assembly of a main printed circuit board and an optoelectronic module, according to one or more embodiments shown and described herein;

FIG. 6 schematically depicts a perspective view of an assembly of a main printed circuit board and an optoelectronic module, according to one or more embodiments shown and described herein; and

FIG. 7 schematically depicts a plan view of a plurality of optoelectronic modules coupled to a main printed circuit board, according to one or more embodiments shown and described herein.

### DETAILED DESCRIPTION

Embodiments of the present disclosure are directed to optoelectronic modules and assemblies comprising optoelectronic modules. As will be explained in detail below, embodiments of the assemblies described herein include an optoelectronic module, which is separate from a main printed circuit board, and one or more electrical connectors that plug into mating electrical connectors of the main printed circuit board. The optoelectronic modules and assemblies described herein consume a smaller amount of surface area of a main printed circuit board compared to applications in which an optoelectronic component is mounted directly to the main printed circuit board. The smaller amount of surface area consumed by the optoelectronic modules and assemblies described herein allows more optoelectronic components to be coupled to a main printed circuit board and/or frees up surface area on the main printed circuit board for other purposes. Moreover, coupling optoelectronic components to an optoelectronic module separate from the main printed circuit board, as described herein, reduces the complexity of the main printed circuit board, allowing for the main printed circuit board to be more reliably manufactured and more inexpensively manufactured. In addition, the assemblies described herein provide for a simple interface between the main printed circuit board and the optoelectronic module that may utilize standard off the shelf connector components while maintaining high performances at a wide frequency range. The optoelectronic modules and assemblies described herein may also facilitate simple assembly, maintenance, debugging, and testing. Various optoelectronic modules and assemblies comprising optoelectronic components are described in detail below.

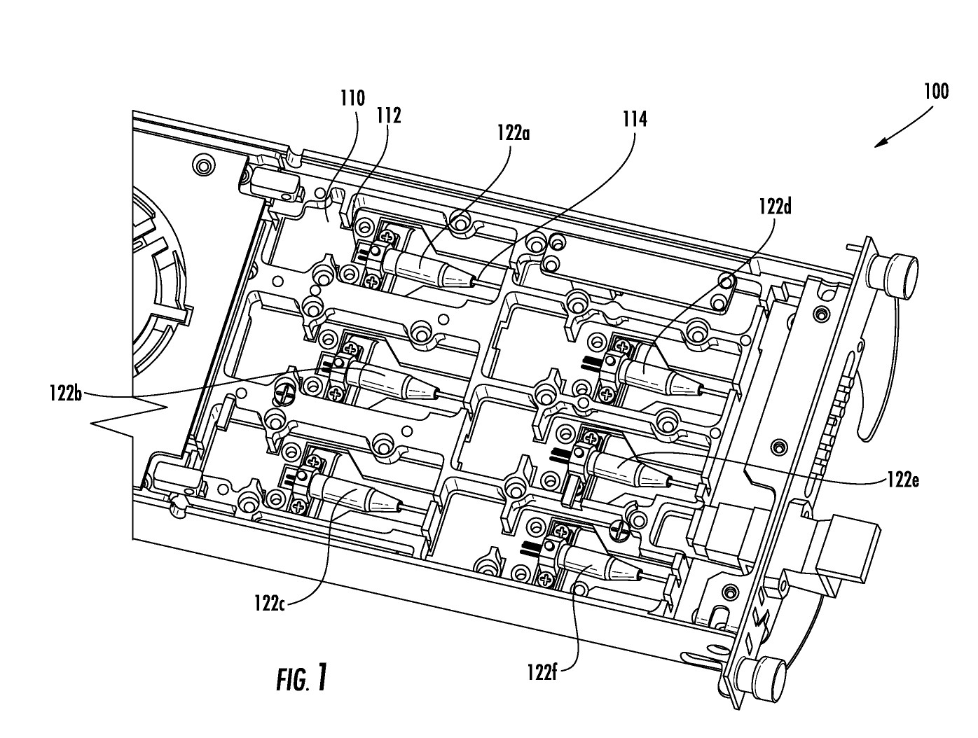

Optoelectronic components, such as laser diodes and photodiodes may be used in a variety of applications, such as to transmit information via light. For example, in some applications, optoelectronic components may be included as part of a radio frequency distributed antenna system application. Such optoelectronic components are provided in a plurality of packages. In some embodiments, the optoelectronic components have a transistor outline semiconductor package. Such optoelectronic components that have a transistor outline semiconductor package may be readily available and inexpensive. In some embodiments, such optoelectronic components are electrically coupled to a main printed circuit board. Referring now to FIG. 1, a conventional assembly of optoelectronic components to a main printed circuit board of a distributed antenna system module 100 is schematically depicted. The assembly includes a plurality of laser diodes 122a-122f mounted to and electrically coupled to a main printed circuit board 110. Each of the plurality of laser diodes 122a-122f includes a plurality of conductive pins for connection to the main printed circuit board 110. Each of the plurality of laser diodes 122a-122f are oriented parallel to a plane of the main printed circuit board 110, such that the plurality of conductive pins extend parallel to the plane of the main printed circuit board 110, as shown for the first laser diode 122a whose pins are positioned in a recess 112. In order to optimize RF performance, each of the plurality of laser diodes 122a-122f are positioned in a cutout of the main printed circuit board 110, as exemplified by the first laser diode 112a positioned in a cutout 114. However, placing the plurality of laser diodes 122a-122f in corresponding cutouts in the main printed circuit board 110 to optimize RF performance consumes a large amount of surface area of the main printed circuit board, thereby limiting the number of optoelectronic components that can be mounted to the main printed circuit board and limiting the number of other electronic components that can be mounted to the main printed circuit board 110. Furthermore, in order to allow for each of the plurality of laser diodes 122a-122f to be assembled to the main printed circuit board 110 in a manner that avoids physical stress on the plurality of conductive pins of each diode (i.e., to avoid degradation of electrical or RF performance as a result of physical stress on the pins), it may be necessary to form a plurality of recesses in the main printed circuit board, such as the recess 112 into which the plurality of pins of the first laser diode 122a are received. However, manufacturing such a main printed circuit board with a plurality of recesses and cutouts to accommodate the plurality of laser diodes 122a-122f as shown in FIG. 1 may be expensive, low-yielding, and difficult.

Accordingly, the inventors have discovered that the optoelectronic modules and assemblies comprising optoelectronic modules described herein facilitate the easier, cheaper, and more reliable manufacturing of less complex main printed circuit boards, and reduce the footprint of optoelectronic components coupled to the main printed circuit board.

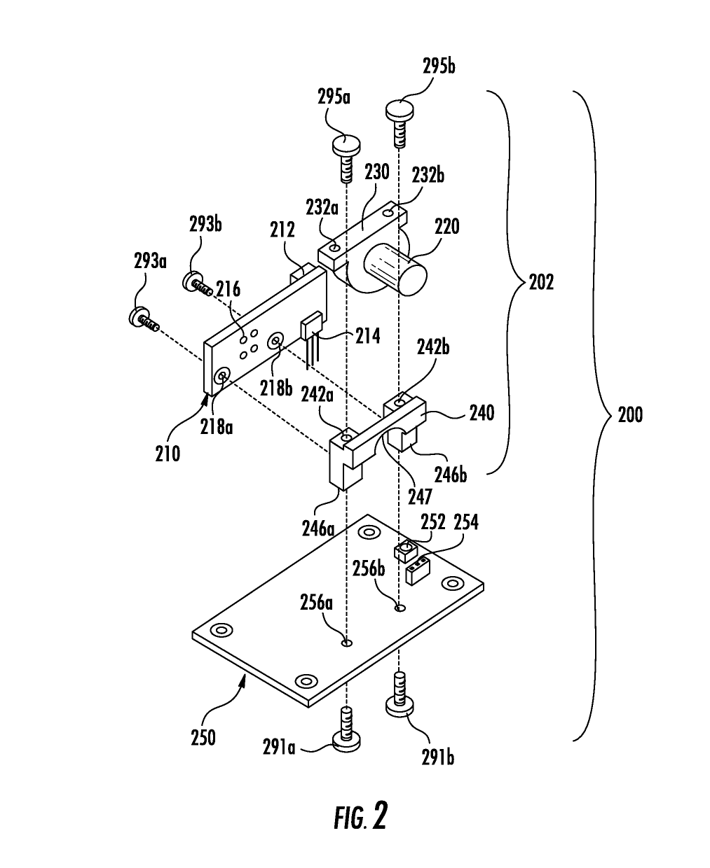

Referring now to FIG. 2, an exploded view of an assembly 200 including an optoelectronic module 202 and a main printed circuit board 250 is schematically depicted. The optoelectronic module 202 includes an optoelectronic module printed circuit board 210, an optoelectronic component 220, a radio frequency electrical connector 212, a digital electrical connector 214, a securing member 230, and a mounting bracket 240. As shown in FIG. 2, the main printed circuit board 250 includes a mating radio frequency electrical connector 252 affixed to a substrate of the main printed circuit board 250 and a mating digital electrical connector 254 affixed to the substrate of the main printed circuit board 250.

Still referring to FIG. 2, the optoelectronic component 220 may be any component capable of transforming electrical energy to light or of transforming light to electrical energy. For example, in some embodiments, the optoelectronic component includes a laser diode or a photodiode. The optoelectronic component 220 depicted in FIG. 2 has a transistor outline semiconductor package. Such an optoelectronic component 220 may be readily available for inexpensive purchase and may be incorporated into the optoelectronic module 202 as described herein. However, it should be understood that in other embodiments the optoelectronic component 220 does not have a transistor outline semiconductor package, such as in embodiments in which the optoelectronic component 220 has a different semiconductor package, such as a butterfly semiconductor package, a through hole semiconductor package, a surface mount semiconductor package, a chip mount semiconductor package, or the like. While the embodiments described herein include only a single optoelectronic component 220 mounted to the optoelectronic module printed circuit board 210, it should be understood that in other embodiments the optoelectronic modules may include more than one optoelectronic component mounted to the optoelectronic module printed circuit board 210.

Still referring to FIG. 2, the radio frequency electrical connector 212 is affixed to the optoelectronic module printed circuit board 210. As will be explained below, the radio frequency electrical connector 212 is in electrical communication with a radio frequency input of the optoelectronic component 220 when the optoelectronic component 220 is mounted to the optoelectronic module printed circuit board 210. In some embodiments, the radio frequency electrical connector 212 is an MMCX connector or other coaxial connector, though embodiments are not limited thereto. Some embodiments may not include the radio frequency electrical connector 212, such as in embodiments in which the optoelectronic component 220 receives input only from a digital electrical connector, or the like. The radio frequency electrical connector 212 is configured to removably plug into a mating radio frequency electrical connector 252 of the main printed circuit board 250. In such embodiments, the radio frequency electrical connector 212 and the mating radio frequency electrical connector 252 may be male and female radio frequency electrical connectors, though embodiments are not limited thereto.

Still referring to FIG. 2, the digital electrical connector 214 is affixed to the optoelectronic module printed circuit board 210. As will be explained below, the digital electrical connector 214 is in electrical communication with a digital input of the optoelectronic component 220 when the optoelectronic component 220 is mounted to the optoelectronic module printed circuit board 210. In some embodiments, the digital electrical connector 214 is a multi-pin connector, though embodiments are not limited thereto. As will be explained below, the digital electrical connector 214 may facilitate the transmission of digital signals (e.g., a gain control signal, a biasing signal, an enable signal, a DC power signal, or the like) to the digital input of the optoelectronic component 220. Some embodiments may not include the digital electrical connector 214, such as in embodiments in which the optoelectronic component 220 receives input only from a radio frequency connector, or the like. The digital electrical connector 214 is configured to removably plug into a mating digital electrical connector 254 of the main printed circuit board 250. In such embodiments, the digital electrical connector 214 and the mating digital electrical connector 254 may be male and female digital electrical connectors, though embodiments are not limited thereto.

Still referring to FIG. 2, the securing member 230 may facilitate the mounting of the optoelectronic component 220 to the optoelectronic module printed circuit board 210 in conjunction with the mounting bracket 240. In the embodiment depicted in FIG. 2, the securing member 230 receives a portion of the optoelectronic component 220 such that another portion of the optoelectronic component 220 protrudes from the securing member 230. In other embodiments, the securing member 230 may receive the entire length of the optoelectronic component 220. The securing member 230 may be secured to the mounting bracket 240 with securing members 295a, 295b (e.g., screws, pins, or the like) that traverse through holes 232a, 232b, and engage securing apertures 242a, 242b of the mounting bracket 240. In embodiments in which the securing members 295a, 295b are screws, the securing apertures 242a, 242b may be threaded, though embodiments are not limited thereto. When the securing member 230 is secured to the mounting bracket 240, the optoelectronic component 220 is engaged by an optoelectronic component engagement surface 247 of the mounting bracket 240. The mounting bracket 240 is affixed to the optoelectronic module printed circuit board 210 with securing members 293a, 293b (e.g., screws, pins, or the like) that traverse through holes 218a, 218b of the optoelectronic module printed circuit board 210, and engage securing apertures of the mounting bracket.

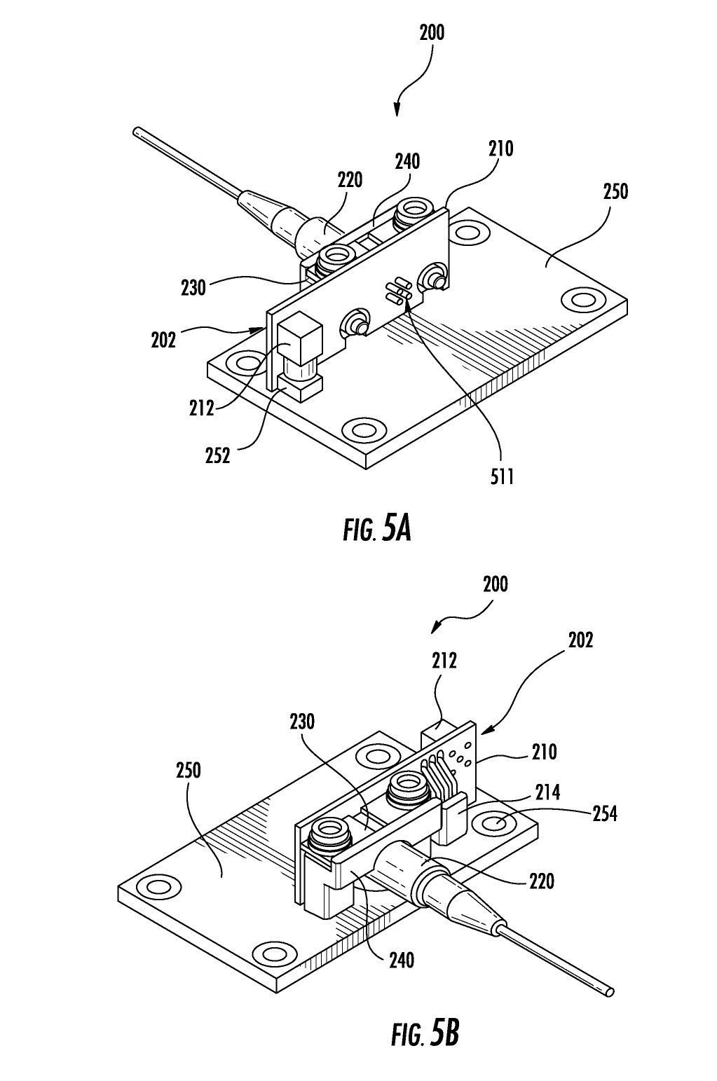

Still referring to FIG. 2, in some embodiments the optoelectronic component includes a plurality of conductive pins (e.g., pins 511 as shown in FIG. 5A) and the optoelectronic module printed circuit board 210 includes a plurality of vias 216 (FIG. 2). In such embodiments, during the process of securing the mounting bracket 240 to the optoelectronic module printed circuit board 210 (and thereby mounting the optoelectronic component 220 to the optoelectronic module printed circuit board 210), the plurality of conductive pins of the optoelectronic component 220 traverse the plurality of vias 216 of the optoelectronic module printed circuit board 210 and may be soldered to the optoelectronic module printed circuit board 210.

Securing the optoelectronic component 220 to the securing member 230, securing the securing member 230 to the mounting bracket 240, and affixing the mounting bracket 240 to the optoelectronic module printed circuit board 210 effectively mounts the optoelectronic component 220 to the optoelectronic module printed circuit board 210.

Still referring to FIG. 2, in other embodiments, the optoelectronic component 220 may be mounted to the optoelectronic module printed circuit board 210 in other ways. For example, some embodiments do not include a securing member 230, such as embodiments in which the optoelectronic component 220 is mounted to the optoelectronic module printed circuit board 210 via only the mounting bracket 240. Furthermore, in some embodiments the securing member 230 and the mounting bracket 240 may be formed as integral pieces. Some embodiments do not include the securing member 230 or the mounting bracket 240, such as embodiments in which the optoelectronic component 220 is mounted directly to the optoelectronic module printed circuit board 210.

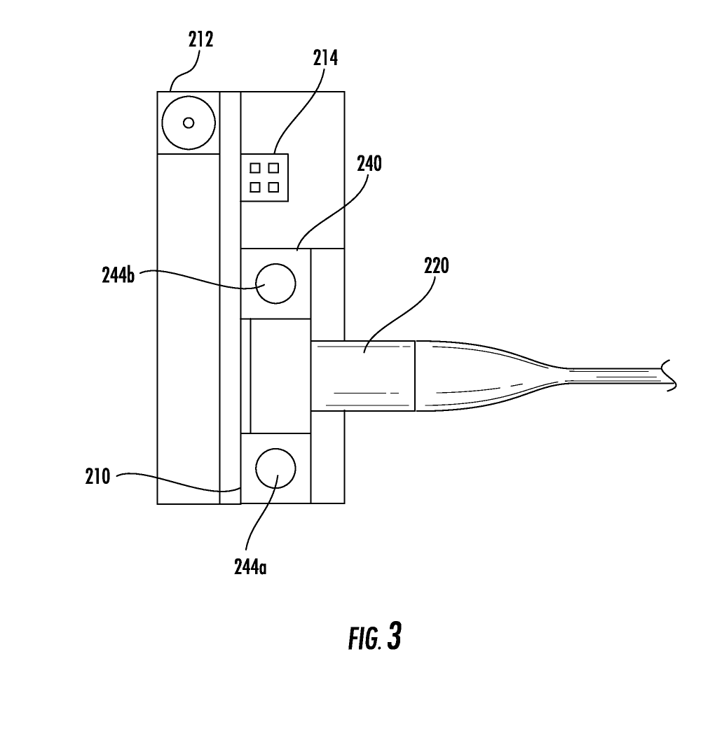

Still referring to FIG. 2, the mounting bracket 240 may be secured to the main printed circuit board 250 such that the optoelectronic module 202 and the components thereon are coupled to the main printed circuit board 250. In the embodiment depicted in FIG. 2, the mounting bracket 240 is secured to the main printed circuit board 250 with securing members 291a, 291b (e.g., screws, pins, or the like) that traverse through holes 256a, 256b of the main printed circuit board 250, and engage securing apertures 244a, 244b (FIG. 3) of the mounting bracket 240. In embodiments in which the securing members 291a, 291b are screws, the securing apertures 244a, 244b of the mounting bracket 240 may be threaded, though embodiments are not limited thereto. As depicted in FIG. 2, the mounting bracket 240 includes a main printed circuit board engagement surface 246a, 246b that engages the main printed circuit board 250 when the mounting bracket 240 is secured to the main printed circuit board 250, thereby increasing the mechanical integrity of the assembly 200.

In some embodiments, the mounting bracket 240 is electrically conductive and an external surface of the optoelectronic component 220 is in electrical communication with the mounting bracket 240 (e.g., when the optoelectronic component engagement surface 247 of the mounting bracket 240 engages the optoelectronic component 220). In such embodiments, the mounting bracket 240 may also be in electrical communication with a ground of the main printed circuit board 250 when the mounting bracket 240 is secured to the main printed circuit board 250, thereby grounding the external surface of the optoelectronic component 220 to the ground of the main printed circuit board 250. In some embodiments, the mounting bracket 240 may not be electrically conductive, the external surface of the optoelectronic component 220 may not be in electrical communication with the mounting bracket 240, and/or the mounting bracket 240 may not be in electrical communication with a ground of the main printed circuit board 250.

When the optoelectronic module 202 is coupled to the main printed circuit board 250, the radio frequency electrical connector 212 of the optoelectronic module printed circuit board 210 is removably plugged into the mating radio frequency electrical connector 252 of the main printed circuit board 250, such that the radio frequency electrical connector 212 of the optoelectronic module 202 is in electrical communication with the mating radio frequency electrical connector 252 of the main printed circuit board 250. Similarly, the digital electrical connector 214 of the optoelectronic module printed circuit board 210 is removably plugged into the mating digital electrical connector 254 of the main printed circuit board 250, such that the digital electrical connector 214 of the optoelectronic module 202 is in electrical communication with the mating digital electrical connector 254 of the main printed circuit board 250.

It should be understood that the mechanical layout and architecture of the optoelectronic module 202 and the assembly 200 provides stable impedance and overall performance. Furthermore, the embodiments described herein a smaller amount of surface area on the main printed circuit board than embodiments that mount the optoelectronic components directly to the main printed circuit board.

FIG. 3 schematically depicts a bottom view of the optoelectronic module 202 of FIG. 2. As shown in FIG. 3, the optoelectronic module 202 includes the optoelectronic module printed circuit board 210, the radio frequency electrical connector 212 affixed to the optoelectronic module printed circuit board 210, the digital electrical connector 214 affixed to the optoelectronic module printed circuit board 210, the mounting bracket 240 affixed to the optoelectronic module printed circuit board 210, and the optoelectronic component 220 mounted to the optoelectronic module printed circuit board 210. As shown in FIG. 3, the optoelectronic component 220 is mounted to the optoelectronic module printed circuit board 210 with the mounting bracket 240.

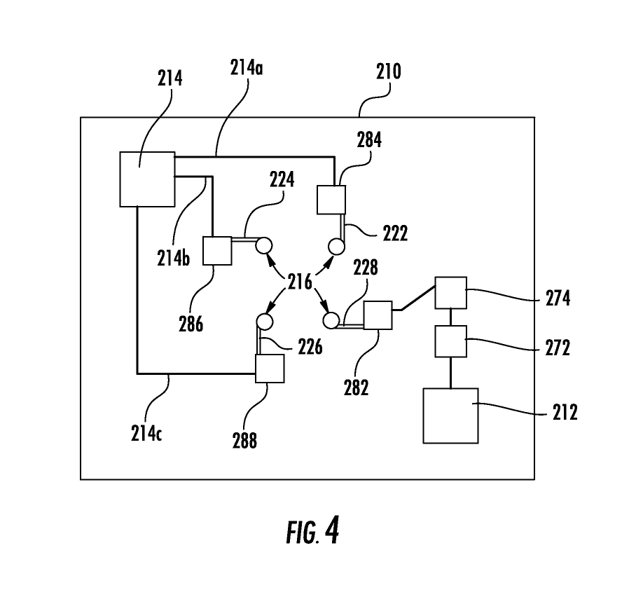

FIG. 4 schematically depicts a circuit diagram illustrating the interconnection of the radio frequency electrical connector 212 (FIG. 2) and the digital electrical connector 214 (FIG. 2) to a plurality of input pins 222, 224, 226, and 228 of the optoelectronic component 220 (FIG. 2). As shown in FIG. 4, the radio frequency electrical connector 212 is in electrical communication with a radio frequency input pin 228 of the optoelectronic component. In some embodiments, one or more passive components 272 are affixed to the optoelectronic module printed circuit board 210 and are in electrical communication with the radio frequency input pin 228. In some embodiments, an amplifier 274, which may also include an attenuator, is affixed to the optoelectronic module printed circuit board 210 and in electrical communication with the radio frequency electrical connector 212 and the radio frequency input pin 228. In some embodiments, one or more impedance matching components (e.g., a tuned stub, a quarter wave transformer, or the like) may be affixed to the optoelectronic module printed circuit board 210 and may be in electrical communication with the radio frequency electrical connector 212 and the radio frequency input pin 228.

Still referring to FIG. 4, the digital electrical connector 214 is in electrical communication with a plurality of digital input pins 222, 224, 226 of the optoelectronic component. A plurality of soldering pads 282, 284, 286, and 288 are offset from the plurality of vias 216. The plurality of soldering pads 282, 284, 286, and 288 electrically couple the plurality of input pins 222, 224, 226, 228 of the optoelectronic component to the respective outputs of the radio frequency electrical connector 212 and the digital electrical connector 214. In some embodiments, one or more of the plurality of input pins 222, 224, 226, 228 of the optoelectronic component may be electrically coupled to an electrical ground. In some embodiments, no copper may be included in the vias. It should be understood that many different layouts may be used in order to fit to a variety of optoelectronic components (e.g., a variety of optoelectronic components having transistor outline semiconductor packages, or any other semiconductor package), while keeping the same mechanical and electrical interface with the main printed circuit board. By soldering to soldering pads outside of the vias, capacitance may be minimized. It may be desirable to design the layout of the optoelectronic module printed circuit board 210 to minimize the size of the board in order to eliminate capacitance of RF traces and to enable the use of a low cost printed circuit board substrate (e.g., FR4 or the like). A further benefit of designing the optoelectronic module printed circuit board 210 to have a small footprint is to eliminate the need for complex impedance matching.

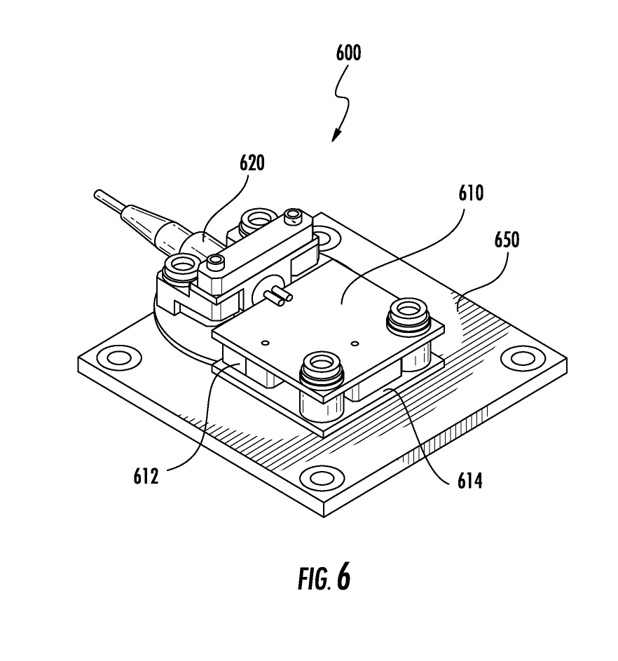

The optoelectronic module printed circuit board 210 may be oriented in several manners relative to the main printed circuit board 250 when the optoelectronic module printed circuit board 210 and the main printed circuit board 250 are assembled. For example, FIGS. 5A and 5B schematically depict a rear perspective view (FIG. 5A) and front perspective view (FIB. 5B) of an assembly 200 of the main printed circuit board 250 and the optoelectronic module 202 described above with respect to FIG. 2. As shown in FIGS. 5A and 5B, the optoelectronic module 202 is coupled to the main printed circuit board 250 such that the optoelectronic module printed circuit board 210 is perpendicular to the main printed circuit board 250. This perpendicular arrangement allows for significant space savings on the main printed circuit board 250. FIG. 6 schematically depicts a perspective view of an assembly 600 of a main printed circuit board 650 and an optoelectronic module in which the optoelectronic module printed circuit board 610 is parallel to the main printed circuit board 650 FIG. 6 also depicts an optoelectronic component 620, a mating radio frequency electrical connector assembly 612, and a mating digital electrical connector assembly 614, each of which may include any of the corresponding components described above with respect to FIG. 2.

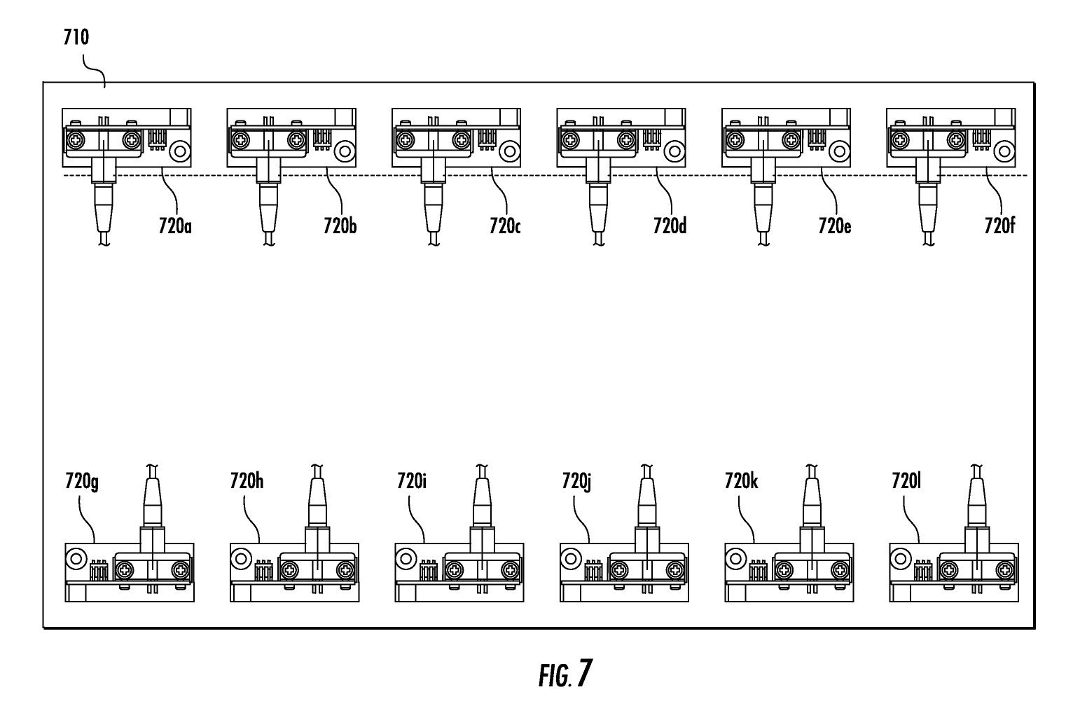

FIG. 7 schematically depicts a plan view of a plurality of optoelectronic modules 720a-720l (i.e., any of the optoelectronic modules described herein) to a main printed circuit board 700. Space saving benefits are realized as a result of the configuration of FIG. 7 because the optoelectronic modules described herein take up less space on the main printed circuit board 700 than embodiments in which the optoelectronic components are mounted directly to the main printed circuit board 700 (e.g., as described above with reference to FIG. 1). The saved space may allow more optoelectronic modules to be coupled to the main printed circuit board 700, may allow the main printed circuit board 700 to be smaller, and/or may allow for freed space on the main printed circuit board 700 to be used for other components.

Referring once again to FIGS. 2 and 4, a method of assembling an optoelectronic module 202 according to the embodiments shown and described herein includes providing an optoelectronic module printed circuit board 210 including a plurality of vias 216 and a plurality of soldering pads 282, 284, 286, 288 (FIG. 4) offset from the plurality of vias 216. The radio frequency electrical connector 212 and the digital electrical connector 214 may then be affixed to the optoelectronic module printed circuit board 210. The mounting bracket 240 may be affixed to the optoelectronic module printed circuit board 210. The optoelectronic component 220 may be mounted to the optoelectronic module printed circuit board 210 with the mounting bracket 240. The plurality of pins of the optoelectronic component 220 may be passed through the plurality of vias 216 of the optoelectronic module printed circuit board 210. Finally, the plurality of pins may be soldered to the plurality of soldering pads. In some embodiments, the plurality of pins may be cut to a proper length and bent before soldering the plurality of pins to the plurality of soldering pads. In some embodiments, the electrical connectors and mounting components may be assembled before the optoelectronic component 220 is assembled to the optoelectronic module printed circuit board 210. The pins may be bent and soldered to the soldering pads as the last step of assembling the optoelectronic module in some embodiments, which may result in lower mechanical stress on the pins than if the pins were bent and soldered before other assembly steps. In other embodiments, the optoelectronic module may be assembled differently, such as embodiments that combine or omit any of the preceding steps, or embodiments that perform the preceding steps in a different order.

Once the optoelectronic module 202 is assembled (e.g., as described in the preceding paragraph), the optoelectronic module 202 and the main printed circuit board 250 may be assembled. For example, a method of assembling an optoelectronic module 202 and a main printed circuit board 250 includes providing an optoelectronic module 202 (i.e., any optoelectronic module described above), providing a main printed circuit board 250 having a mating electrical connector (e.g., the mating radio frequency electrical connector 252 or the mating digital electrical connector 254), and plugging an electrical connector (e.g., the radio frequency electrical connector 212 or the digital electrical connector 214) of the optoelectronic module printed circuit board 210 into the mating electrical connector of the main printed circuit board 250, such that the electrical connector of the optoelectronic module 202 is in electrical communication with the mating electrical connector of the main printed circuit board 250. In some embodiments, the optoelectronic module 202 is secured to the main printed circuit board 250 with the mounting bracket 240 as described above. In other embodiments, the optoelectronic module and the main printed circuit board may be assembled differently.

It should now be understood that embodiments described herein are directed to optoelectronic modules and assemblies comprising optoelectronic modules. The optoelectronic modules and assemblies described herein consume a smaller amount of surface area of a main printed circuit board compared to applications in which an optoelectronic component is mounted directly to the main printed circuit board. The smaller amount of surface area consumed by the optoelectronic modules and assemblies described herein allows more optoelectronic components to be coupled to a main printed circuit board and/or frees up surface area on the main printed circuit board for other purposes. Moreover, coupling optoelectronic components to an optoelectronic module separate from the main printed circuit board, as described herein, reduces the complexity of the main printed circuit board, allowing for the main printed circuit board to be more reliably manufactured and more inexpensively manufactured. In addition, the assemblies described herein provide for a simple interface between the main printed circuit board and the optoelectronic module that may utilize standard off the shelf connector components while maintaining high performances at a wide frequency range. The optoelectronic modules and assemblies described herein may also facilitate simple assembly, maintenance, debugging, and testing.

For the purposes of describing and defining the subject matter of the disclosure it is noted that the term “substantially” is utilized herein to represent the inherent degree of uncertainty that may be attributed to any quantitative comparison, value, measurement, or other representation.

It will be apparent to those skilled in the art that various modifications and variations can be made without departing from the spirit or scope of the disclosure. Since modifications, combinations, sub-combinations and variations of the disclosed embodiments incorporating the spirit and substance of the disclosure may occur to persons skilled in the art, the embodiments disclosed herein should be construed to include everything within the scope of the appended claims and their equivalents.

What is claimed is:

1. An assembly comprising an optoelectronic module coupled to a main printed circuit board, wherein:
the optoelectronic module comprises:
an optoelectronic module printed circuit board;
an optoelectronic component mounted to the optoelectronic module printed circuit board;
an electrical connector affixed to the optoelectronic module printed circuit board, wherein the electrical connector is in electrical communication with an input of the optoelectronic component;
a mounting bracket affixed to the optoelectronic module printed circuit board, wherein the mounting bracket includes:
an optoelectronic component engagement surface for engaging the optoelectronic component; and
a main printed circuit board engagement surface that engages the main printed circuit board;
the main printed circuit board comprises a mating electrical connector;
the electrical connector of the optoelectronic module is removably plugged into the mating electrical connector of the main printed circuit board, such that the electrical connector of the optoelectronic module is in electrical communication with the mating electrical connector of the main printed circuit board; and
the mounting bracket is secured to the main printed circuit board such that the optoelectronic module is coupled to the main printed circuit board.

2. The assembly of claim 1, wherein the optoelectronic component has a transistor outline semiconductor package, and wherein the optoelectronic component includes a laser diode or a photodiode.

3. The assembly of claim 1, wherein:
the electrical connector of the optoelectronic module is a radio frequency electrical connector;
the mating electrical connector of the main printed circuit board is a mating radio frequency electrical connector;
the input of the optoelectronic component is a radio frequency input;
the radio frequency electrical connector is in electrical communication with the radio frequency input of the opto electronic component;
the radio frequency electrical connector is removably plugged into the mating radio frequency electrical connector of the main printed circuit board, such that the radio frequency electrical connector of the optoelectronic module is in electrical communication with the mating radio frequency electrical connector of the main printed circuit board;
the optoelectronic module further comprises a digital electrical connector affixed to the optoelectronic module printed circuit board;
the main printed circuit board further comprises a mating digital electrical connector;
the digital electrical connector is in electrical communication with a digital input of the optoelectronic component; and
the digital electrical connector is removably plugged into the mating digital electrical connector of the main printed circuit board, such that the digital electrical connector of the optoelectronic module is in electrical communication with the mating digital electrical connector of the main printed circuit board.

4. The assembly of claim 1, wherein the optoelectronic module printed circuit board is parallel to the main printed circuit board.

5. The assembly of claim 1, wherein the optoelectronic module printed circuit board is perpendicular to the main printed circuit board.

6. The assembly of claim 5, wherein
the optoelectronic component includes a plurality of conductive pins;
the optoelectronic module printed circuit board includes a plurality of vias; and
the plurality of conductive pins of the optoelectronic component traverse the plurality of vias of the optoelectronic module printed circuit board.

7. The assembly of claim 1, wherein:
the mounting bracket is electrically conductive;
an external surface of the optoelectronic component is in electrical communication with the mounting bracket; and
the mounting bracket is in electrical communication with a ground of the main printed circuit board.

8. The assembly of claim 1, wherein:
the mounting bracket includes a threaded aperture;
the main printed circuit board includes a through hole; and
a screw traverses the through hole and engages the threaded aperture, thereby securing the main printed circuit board to the mounting bracket to couple the optoelectronic module to the main printed circuit board.

9. An assembly comprising an optoelectronic module coupled to a main printed circuit board, wherein:
the optoelectronic module comprises:
an optoelectronic module printed circuit board;
an optoelectronic component mounted to the optoelectronic module printed circuit board, wherein the optoelectronic component has a transistor outline semiconductor package;
a radio frequency electrical connector affixed to the optoelectronic module printed circuit board, wherein the radio frequency electrical connector is in electrical communication with a radio frequency input of the optoelectronic component;
a digital electrical connector affixed to the optoelectronic module printed circuit board, wherein the digital electrical connector is in electrical communication with a digital input of the opto electronic component;
a mounting bracket affixed to the optoelectronic module printed circuit board, wherein the mounting bracket includes:
an optoelectronic component engagement surface for engaging the optoelectronic component; and
a main printed circuit board engagement surface for engaging the main printed circuit board;
the main printed circuit board comprises a mating radio frequency electrical connector and a mating digital electrical connector;
the radio frequency electrical connector of the optoelectronic module is removably plugged into the mating radio frequency electrical connector of the main printed circuit board, such that the radio frequency electrical connector of the optoelectronic module is in electrical communication with the mating radio frequency electrical connector of the main printed circuit board;
the digital electrical connector of the optoelectronic module is removably plugged into the mating digital electrical connector of the main printed circuit board, such that the digital electrical connector of the optoelectronic module is in electrical communication with the mating digital electrical connector of the main printed circuit board; and
the mounting bracket is secured to the main printed circuit board such that the optoelectronic module is coupled to the main printed circuit board.

10. The assembly of claim 9, wherein the optoelectronic component includes a laser diode or a photodiode.

11. The assembly of claim 9, wherein the optoelectronic module printed circuit board is parallel to the main printed circuit board.

12. The assembly of claim 9, wherein the optoelectronic module printed circuit board is perpendicular to the main printed circuit board.

13. An optoelectronic module comprising:
an optoelectronic module printed circuit board;
an optoelectronic component mounted to the optoelectronic module printed circuit board;
an electrical connector affixed to the optoelectronic module printed circuit board, wherein the electrical connector is in electrical communication with an input of the optoelectronic component, wherein the electrical connector is configured to removably plug into a mating electrical connector of a main printed circuit board; and
a mounting bracket affixed to the optoelectronic module printed circuit board, wherein the mounting bracket includes:
an optoelectronic component engagement surface for engaging the optoelectronic component; and
a main printed circuit board engagement surface for engaging the main printed circuit board.

14. The optoelectronic module of claim 13, wherein the optoelectronic component has a transistor outline semiconductor package, and wherein the optoelectronic component includes a laser diode or a photodiode.

15. The optoelectronic module of claim 13, wherein:
the electrical connector is a radio frequency electrical connector;
the input of the optoelectronic component is a radio frequency input;
the radio frequency electrical connector is in electrical communication with the radio frequency input of the optoelectronic component;
the radio frequency electrical connector is configured to removably plug into a mating radio frequency electrical connector of the main printed circuit board;
the optoelectronic module further comprises a digital electrical connector affixed to the optoelectronic module printed circuit board;
the digital electrical connector is in electrical communication with a digital input of the optoelectronic component; and
the digital electrical connector is configured to removably plug into a mating digital electrical connector of the main printed circuit board.

16. The optoelectronic module of claim 13, wherein:
the optoelectronic component includes a plurality of conductive pins;
the optoelectronic module printed circuit board includes a plurality of vias; and
the plurality of conductive pins of the optoelectronic component traverse the plurality of vias of the optoelectronic module printed circuit board.

17. The optoelectronic module of claim 16, wherein:
the optoelectronic module printed circuit board includes a plurality of soldering pads spaced apart from the plurality of vias; and
the plurality of conductive pins are soldered to the plurality of soldering pads.

18. The optoelectronic module of claim 13, further comprising an amplifier affixed to the optoelectronic module printed circuit board, wherein the amplifier is in electrical communication with the electrical connector and is in electrical communication with the input of the optoelectronic component.

19. The optoelectronic module of claim 13, further comprising one or more passive electronic components affixed to the optoelectronic module printed circuit board, wherein the one or more passive electronic components are in electrical communication with the input of the optoelectronic component.

20. The optoelectronic module of claim 13, further comprising one or more impedance matching components affixed to the optoelectronic module printed circuit board, wherein the one or more impedance matching components are in electrical communication with the input of the optoelectronic component.

21. The optoelectronic module of claim 13, wherein:
the mounting bracket is electrically conductive; and
an external surface of the optoelectronic component is in electrical communication with the mounting bracket.

22. A method of assembling an optoelectronic module and a main printed circuit board, the method comprising:
providing an optoelectronic module comprising:
an optoelectronic module printed circuit board;
an optoelectronic component mounted to the optoelectronic module printed circuit board;
an electrical connector affixed to the optoelectronic module printed circuit board, wherein the electrical connector is in electrical communication with an input of the optoelectronic component;
a mounting bracket affixed to the optoelectronic module printed circuit board, wherein the mounting bracket includes:
an optoelectronic component engagement surface for engaging the optoelectronic component; and
a main printed circuit board engagement surface that engages the main printed circuit board;
providing the main printed circuit board having a mating electrical connector; and
plugging the electrical connector of the optoelectronic module into the mating electrical connector of the main printed circuit board, such that the electrical connector of the optoelectronic module is in electrical communication with the mating electrical connector of the main printed circuit board.

23. The method of claim 22, further comprising securing the main printed circuit board to the optoelectronic module with the mounting bracket.

24. A method of assembling an optoelectronic module, the method comprising:
providing an optoelectronic module printed circuit board including a plurality of vias and a plurality of soldering pads offset from the plurality of vias;
affixing an electrical connector to the opto electronic module printed circuit board;
affixing a mounting bracket to the optoelectronic module printed circuit board;
mounting an optoelectronic component to the optoelectronic module with the mounting bracket;
passing a plurality of pins of the optoelectronic component through the plurality of vias of the optoelectronic module printed circuit board; and
soldering the plurality of pins to the plurality of soldering pads.

25. The method of claim 24, further comprising cutting the plurality of pins, and bending the plurality of pins before soldering the plurality of pins to the plurality of soldering pads.
